(19) United States
(12) Patent Application Publication
(10) Pub. No.: US 2025/0309899 A1
(43) Pub. Date: Oct. 2, 2025

(54) LEVEL SHIFTER

(71) Applicant: Nuvoton Technology Corporation, Hsinchu Science Park (TW)

(72) Inventors: Cheng-Tao LI, Hsinchu Science Park (TW); Wei-Jean LIU, Hsinchu Science Park (TW)

(21) Appl. No.: 19/095,279

(22) Filed: Mar. 31, 2025

(30) Foreign Application Priority Data
Apr. 1, 2024 (TW) 113112293

(51) Int. Cl. H03K 19/0185

(52) U.S. Cl. CPC H03K 19/018521

(57) ABSTRACT

A level shifter is provided, including high-voltage side circuit, bias voltage generating circuit, capacitor, and first to fourth N-type transistors (NTs). The high-voltage side circuit is coupled between a voltage source and first and second output terminals. The bias voltage generating circuit provides bias voltage to a first node. The first NT is coupled between the first output terminal and a second node. A control terminal of the first NT is coupled to the first node. The second NT is coupled between the second node and ground. A control terminal of the second NT is coupled to first input terminal. The third and fourth NTs are coupled in series between the second output terminal and the ground. The control terminals of the third and fourth NTs are coupled to second input terminal. The first and second input terminals respectively receive first and second input signals that are phase-inverted.

### CROSS REFERENCE TO RELATED APPLICATIONS

This application claims priority of Taiwan Patent Application No. 113112293, filed on Apr. 1, 2024, the entirety of which is incorporated by reference herein.

### BACKGROUND OF THE INVENTION

### Field of the Invention

The present invention relates to a level shifter, and, in particular, to a level shifter that has a faster switching speed.

### Description of the Related Art

Conversion between high voltage and low voltage is a common procedure in integrated circuits. Level shifters are most commonly used to perform high-to-low voltage conversion. Level shifters convert a signal from one power domain to another. As the core voltage inside an integrated circuit becomes lower and lower, the transistor in the level shifter cannot switch the signal normally due to the excessive threshold voltage, which further causes the back-end circuits of the level shifter to malfunction. To solve this problem, different circuit architectures are adopted in conventional level shifters. However, these circuit structures reduce the switching speed of the level shifter, increase the occupied area, and increase the manufacturing cost.

### BRIEF SUMMARY OF THE INVENTION

Therefore, the present invention provides a level shifter. The level shifter includes a high-voltage side circuit, a first bias voltage generating circuit, a first capacitor, a first N-type transistor, a second N-type transistor, a third N-type transistor, and a fourth N-type transistor. The high-voltage side circuit is coupled between a first voltage source and first and second output terminals. The first bias voltage generating circuit provides a first bias voltage to a first node. The first capacitor is coupled between the first node and a first input terminal. The first N-type transistor has an input terminal coupled to the first output terminal, an output terminal coupled to a second node, and a control terminal coupled to the first node. The second N-type transistor has an input terminal coupled to the second node, an output terminal coupled to a ground, and a control terminal coupled to the first input terminal. The third N-type transistor has an input terminal coupled to the second output terminal, an output terminal coupled to a third node, and a control terminal coupled to a second input terminal. The fourth N-type transistor has an input terminal coupled to the third node, an output terminal coupled to the ground, and a control terminal coupled to the second input terminal. The first input terminal receives a first input signal, the second input terminal receives a second input signal, wherein the first input signal and the second input signal are inversions if each other.

### BRIEF DESCRIPTION OF THE DRAWINGS

FIG. 1 illustrates a level shifter according to an embodiment of the present invention.

FIGS. 2A and 2B are diagrams of operations of the level shifter according to an embodiment of the present invention.

FIG. 3 illustrates the variation of main voltages of the level shifter according to an embodiment of the present invention.

FIG. 4 illustrates a level shifter according to another embodiment of the present invention.

FIG. 5 illustrates a level shifter according to another embodiment of the present invention.

FIG. 6 illustrates a level shifter according to another embodiment of the present invention.

### DETAILED DESCRIPTION OF THE INVENTION

To make the above-mentioned objects, features, and advantages of the present invention more obvious and easy to understand, a preferred embodiment is provided below and described in detail with reference to the accompanying drawings.

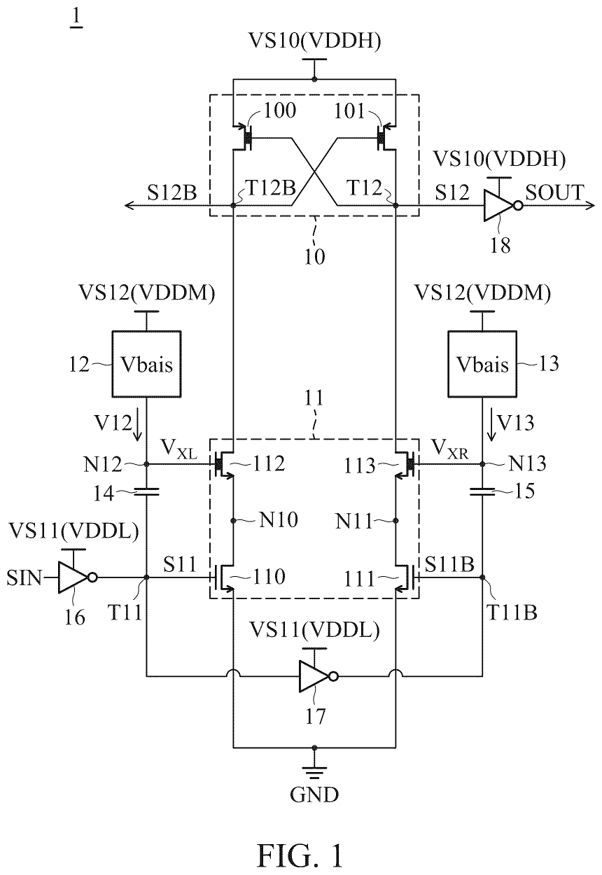

FIG. 1 illustrates a level shifter according to an embodiment of the present invention. Referring to FIG. 1, level shifter 1 includes a high-voltage side circuit 10, a low-voltage side circuit 11, bias voltage generating circuits (or Vbais) 12 and 13, capacitors 14 and 15, and inverters 16-18. The level shifter 1 receives input signals S11 and S11B and performs voltage conversion on the input signals S11 and S11B, i.e., converts the input signals S11 and S11B from one power domain (e.g., the power domain of voltage source VS11) to another power domain (e.g., the power domain of voltage source VS10) to generate an output signal S12 at an output terminal T12 and an output signal S12B at an output terminal T12B. The input signals S11 and S11B are inversions of each other, and the input signal S11B is referred to as an inverted input signal herein; the output signals S12 and S12B are inversions of each other, and the output signal S12B is referred to as an inverted output signal herein.

Referring to FIG. 1, inverters 16 and 17 are powered by the voltage source VS11. In this embodiment, the voltage source VS11 receives supply voltage VDDL. An input terminal of the inverter 16 receives an input signal SIN, and its output terminal is coupled to an input terminal T11 of the level shifter 1. The inverter 16 inverts the input signal SIN to generate the input signal S11 at the input terminal T11. An input terminal of the inverter 17 is coupled to the input terminal T11, and its output terminal is coupled to the input terminal T11B of the level shifter 1. The inverter 17 inverts the input signal S11 to generate an inverted input signal S11B at the input terminal T11B. Since the inverters 16 and 17 are powered by the voltage source VS11, the input signal S11 and the inverted input signal S11B generated by the inverters 16 and 17 are both switching between the supply voltage VDDL (i.e., the first voltage level) and a ground level (i.e., a second voltage level, such as 0 volt (V)) lower than the supply voltage VDDL.

The bias voltage generating circuit 12 is coupled between a voltage source VS12 and a node N12. The capacitor 14 is coupled between the node N12 and the input terminal T11. In this embodiment, the voltage source VS12 receives a supply voltage VDDM. The bias voltage generating circuit 12 generates a bias voltage V12 according to the supply voltage VDDM, and provides the bias voltage V12 to the node N12. Due to the coupling effect of the capacitor 14, when the voltage level of the input signal S11 at the input terminal T11 changes instantaneously, the voltage V_{XL} at the node N12 changes accordingly. Therefore, it can be known that the voltage V_{XL} on the node N12 is determined by the bias voltage V12 and the voltage level of the input signal S11. The bias voltage generating circuit 13 is coupled between the voltage source VS12 and a node N13. The capacitor 15 is coupled between the node N13 and the input terminal T11B. The bias voltage generating circuit 13 generates a bias voltage V13 according to the supply voltage VDDM, and provides the bias voltage V13 to the node N13. Due to the coupling effect of the capacitor 15, when the voltage level of the inverted input signal S11B at the input terminal T11B changes instantaneously, the voltage V_{XR} at the node N13 changes accordingly. Therefore, it can be seen that the voltage V_{XR} on the node N13 is determined by the bias voltage V13 and the voltage level of the inverted input signal S11B.

The low-voltage side circuit 11 includes N-type transistors 110-113. The input terminal of the N-type transistor 110 is coupled to a node N10, its output terminal is coupled to a ground GND, and its control terminal is coupled to the input terminal T11. The input terminal of the N-type transistor 112 is coupled to the output terminal T12B, its output terminal is coupled to the node N10, and its control terminal is coupled to the node N12. The input terminal of the N-type transistor 111 is coupled to a node N11, its output terminal is coupled to the ground GND, and its control terminal is coupled to the input terminal T11B. The input terminal of the N-type transistor 113 is coupled to the output terminal T12, its output terminal is coupled to the node N11, and its control terminal is coupled to the node N13. Therefore, it can be known that the control terminal of the N-type transistor 113 is coupled to the input terminal T11B through the node N13 and the capacitor 15.

In this embodiment, the N-type transistors 110 and 111 are implemented by low-voltage N-type metal-oxide-semiconductor (LV-NMOS) transistors, and the N-type transistors 112 and 113 are implemented by high-voltage N-type metal-oxide-semiconductor (HV-NMOS) transistors. For each of the N-type transistors 110-113, the input terminal, the output terminal, and the control terminal are the drain, the source, and the gate of the NMOS transistor, respectively.

The high-voltage side circuit 10 is coupled between the voltage source VS10 and the output terminals T12 and T12B. In this embodiment, the voltage source VS10 receives a supply voltage VDDH. The high-voltage side circuit 10 includes P-type transistors 100 and 101. The input terminal of the P-type transistor 100 is coupled to the voltage source VS10, its output terminal is coupled to the output terminal T12B, and its control terminal is coupled to the output terminal T12. The input terminal of the P-type transistor 101 is coupled to the voltage source VS10, its output terminal is coupled to the output terminal T12, and its control terminal is coupled to the output terminal T12B. The structure of the high-voltage side circuit 10 shown in FIG. 1 is only an example and is not limited to this in other embodiments.

In this embodiment, the P-type transistors 100 and 101 are implemented by high-voltage P-type metal-oxide-semiconductor (HV-PMOS) transistors. For each of the P-type transistors 100 and 101, the input terminal, the output terminal, and the control terminal are the source, the drain, and the gate of the PMOS transistor, respectively.

Referring to FIG. 1, the inverter 18 is powered by a voltage source VS10. An input terminal of the inverter 18 is coupled to the output terminal T12 to receive the output signal S12. The inverter 18 inverts the output signal S12 to generate an output signal SOUT. In other embodiments, the input terminal of the inverter 18 may be coupled to the output terminal T12B to receive the inverted output signal S12B, and the inverted output signal S12B may be inverted to generate another inverted output signal that is inverted to the output signal SOUT. Since the inverter 18 is powered by the voltage source VS10, the output signal SOUT generated by the inverter 18 switches between a level of the supply voltage VDDM and a level of 0V.

In an embodiment of the present invention, the supply voltage VDDM is greater than the supply voltage VDDL and less than or equal to the supply voltage VDDH (i.e., VDDL<VDDM≤VDDH).

The detailed operation of the level shifter 1 will be described in detail below.

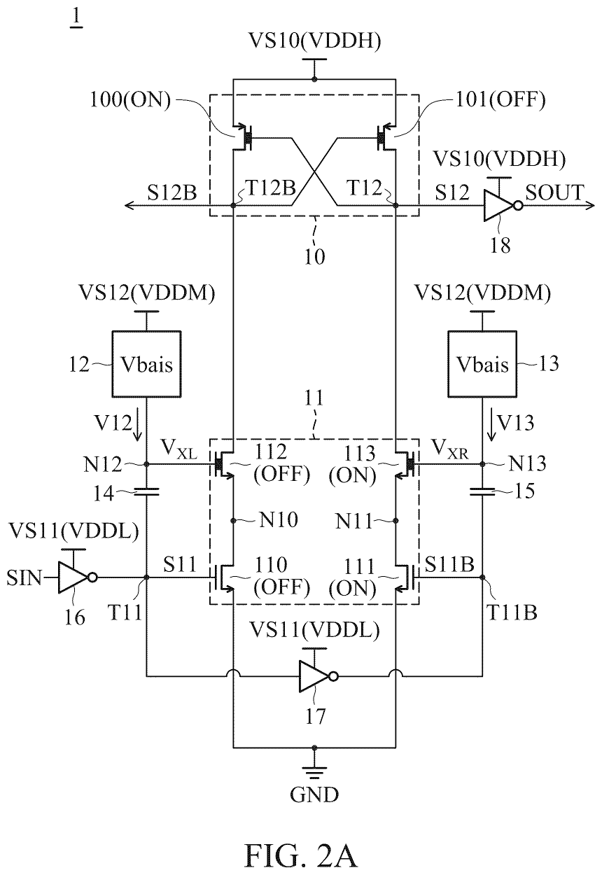

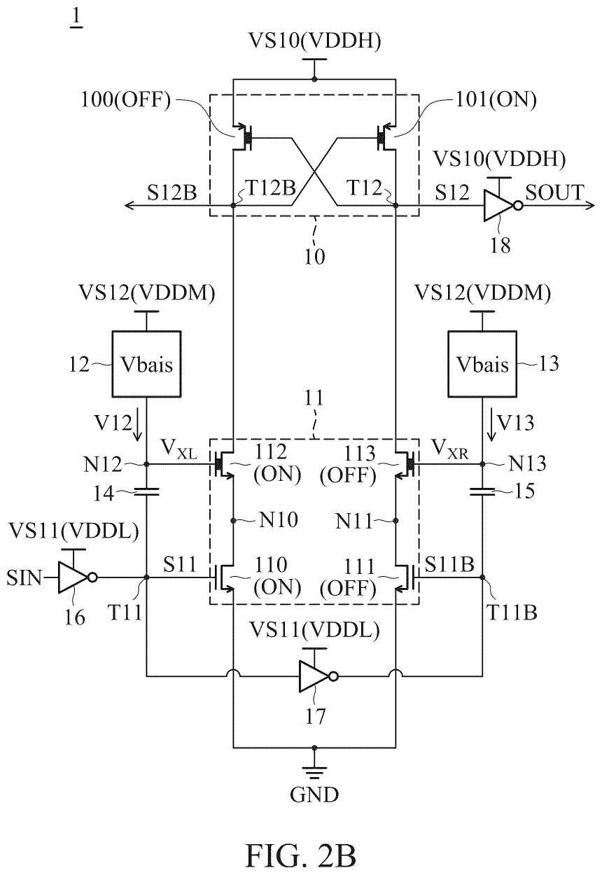

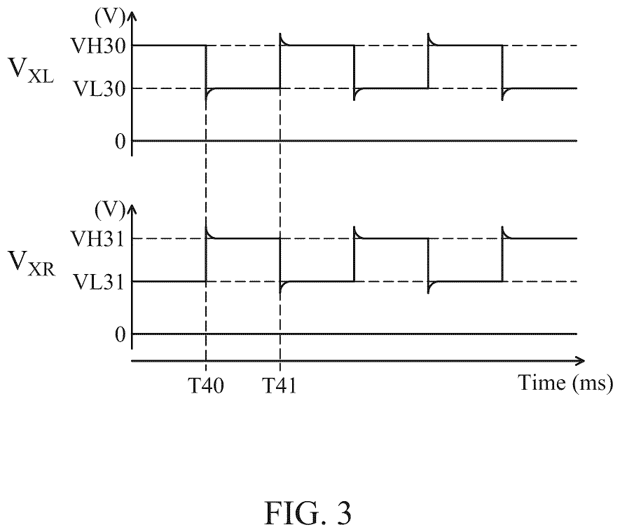

Referring to FIG. 2A and FIG. 3, when the input signal SIN switches from a low voltage level to a high voltage level, the input signal S11 switches from the supply voltage VDDL down to the input signal S11 to turn off the LV-NMOS transistor 110 (i.e., switch to OFF state) through the operation of the inverter 16. In response to the falling edge of the switching of the voltage level of the input signal S11, the voltage V_{XL} at the node N12 switches from a voltage level VH30 down to a voltage level VL30 to turn off the HV-NMOS transistor 112. For example, at time point T40, the voltage V_{XL} switches from the voltage level VH30 down to the voltage level VL30. In this embodiment, the voltage level VL30 is the level of the bias voltage V12.

Through the operation of the inverter 17, the inverted input signal S11B switches from the level of 0V to the level of the supply voltage VDDL to turn on the LV-NMOS transistor 111 (i.e., switch to ON state). Based on the coupling effect of the capacitor 15, the voltage V_{XR} at the node N13 is increased upward from the bias voltage V13. Considering the capacitance C15 of the capacitor 15 and the parasitic capacitance Cpar13 at the node N13, the voltage V_{XR} increases upward from the bias voltage V13 by

$$V DDL \times \frac{C 15}{Cpar 13} ,$$

i.e., the voltage V_{XR} is equal to the sum of the bias voltage V13 and

$$V DDL \times \frac{C 15}{Cpar 13} ( i . e . , {V}_{XR} = V 13 + V DDL \times \frac{C 15}{Cpar 13} ) .$$

Referring to FIG. 3, the voltage V_{XR} on the node N13 switches from the voltage level VL31 up to the voltage level VH31, wherein the voltage level VL31 is the voltage level of the bias voltage V13, and the voltage level VH31 is

$$V 13 + V DDL \times \frac{C 15}{Cpar 13} .$$

For example, at time point T40, the voltage V_{XR} switches from the voltage level VL31 up to the voltage level VH31. At this time, since the LV-NMOS transistor 111 is turned on, the voltage at the source of the HV-NMOS transistor 113 (i.e., the voltage at the node N11) is equal to 0V. The gate-source voltage (Vgs113) of the HV-NMOS transistor 113 is equal to

$$V 13 + V DDL \times \frac{C 15}{Cpar 13} ( i . e . , V gs 113 = V 13 + V DDL \times \frac{C 15}{Cpar 13} )$$

to turn on the HV_NMOS transistor 113. Based on the conduction of the HV-NMOS transistor 113 and the LV-MOS transistor 111, the output signal S12 at the output terminal T12 is switched down to a level of 0V. Through the operation of the inverter 18, the output signal SOUT is switched upward to the level of the supply voltage VDDM.

Based on the output signal S12 at the output terminal T12 being switched down to 0V, the HV-PMOS transistor 100 is turned on, so that the inverted output signal S12B at the output terminal T12B is switched up to the level of the supply voltage VDDH. The HV-PMOS transistor 101 is turned off according to the inverted output signal S12B.

Referring to FIG. 2B and FIG. 3, when the input signal SIN switches from a high voltage level to a low voltage level, the input signal S11 switches from a level of 0V up to a high voltage level of the supply voltage VDDL through the operation of the inverter 16. Through the operation of the inverter 17, the inverted input signal S11B is switched from the level of the supply voltage VDDL down to the level of 0V to turn off the LV-NMOS transistor 111. In response to the falling edge of the switching of the voltage level of the inverting input signal S11B, the voltage V_{XR} at the node N13 switches from the voltage level VH31 down to the voltage level VL31 to turn off the HV-NMOS transistor 113. For example, at time point T41, the voltage V_{XR} switches from the voltage level VH31 down to the voltage level VL31.

In response to the input signal S11 switches from the level of 0V up to the level of the supply voltage VDDL, the LV-NMOS transistor 110 is turned on. Based on the coupling effect of the capacitor 14, the voltage V_{XL} at the node N12 is increased from the bias voltage V12. Considering the capacitance C14 of the capacitor 14 and the parasitic capacitance Cpar12 at the node N12, the voltage V_{XL} increases from the bias voltage V12 by

$$V DDL \times \frac{C 14}{Cpar 12} ,$$

i.e., the voltage V_{XL} is equal to the sum of the bias voltage V12 and

$$V DDL \times \frac{C 14}{Cpar 12} ( i . e . , {V}_{XL} = V 12 + V DDL \times \frac{C 14}{Cpar 12} ) .$$

Referring to FIG. 3, the voltage level VH30, node N12 is switched upward from the voltage level VL30 to the voltage level VH30, wherein the voltage level VH30 is

$$V 12 + V DDL \times \frac{C 14}{Cpar 12} .$$

For example, at time point T41, the voltage V_{XL} switches from the voltage level VL30 up to the voltage level VH30. At this time, since the LV-NMOS transistor 110 is turned on, the voltage at the source of the HV-NMOS transistor 112 (i.e., the voltage at the node N10) is equal to 0V. The gate-source voltage (Vgs112) of the HV-NMOS transistor 112 is equal to

$$V 12 + V DDL \times \frac{C 14}{Cpar 12} ( i . e . , V gs 112 = V 12 + V DDL \times \frac{C 14}{Cpar 12} )$$

to turn on the HV-NMOS transistor 112. Based on the conduction of the HV-NMOS transistor 112 and the LV-MOS transistor 110, the inverted output signal S12B at the output terminal T12B switches down to a level of 0V.

Based on the inverted output signal S12B at the output terminal T12 switches down to 0V, the HV-PMOS transistor 101 is turned on, so that the output signal S12 at the output terminal T12 switches up to the level of the supply voltage VDDH. Through the operation of the inverter 18, the output signal SOUT is switched down to a level of 0V. The HV-PMOS transistor 100 is turned off according to the output signal S12.

Through the above operation, the level shifter 1 converts the input signals S11 and S11B from the power domain of the voltage source VS11 to the power domain of the voltage source VS10, to generate output signals S12 and S12B at the output terminals T12 and T12B respectively, and achieves voltage conversion.

According to the embodiment of the present invention, when the input signal S11 switches from the level of 0V up to the level of the supply voltage VDDL, the gate-source voltage Vgs112 of the HV-NMOS transistor 112 is increased, so that the conduction switching speed of the HV-NMOS transistor 112 is increased to accelerate the inverted output signal S12B to switch down to the level of 0V and accelerate the output signal S12 to switch up to the level of the supply voltage VDDH. When the level of the supply voltage VDDL of the input signal S11 is switched down to 0V, the gate-source voltage Vgs113 of the HV-NMOS transistor 113 is increased, so that the conduction switching speed of the HV-NMOS transistor 113 is increased. The speed at which the output signal S12 switches downward to the level of 0V is accelerated, and the speed at which the inverted output signal S12B switches upward to the level of the supply voltage VDDH is accelerated. Therefore, it can be known that the level shifter 1 of the present invention improves the switching speed of the output signal S12 and the inverted output signal S12B. In addition, the HV-MOS transistors 112 and 113 of the present invention are manufactured by a common process, which does not require a large area and can save manufacturing costs.

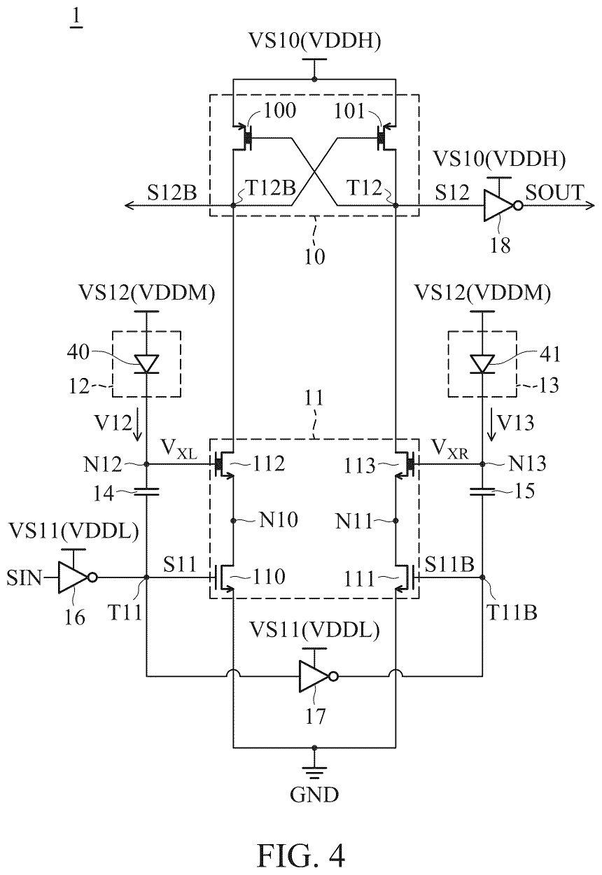

In one embodiment of the present invention, as shown in FIG. 4, the bias voltage generating circuit 12 includes a diode 40, and the bias voltage generating circuit 13 includes a diode 41. An anode of the diode 40 is coupled to the voltage source VS12, and its cathode is coupled to the node N12. An anode of the diode 41 is coupled to the voltage source VS12, and its cathode is coupled to the node N13. Assume that the threshold voltage of the diode 40 is equal to the threshold voltage of the diode 41, both being Vth. The bias voltage V12 generated by the bias voltage generating circuit 12 and the bias voltage V13 generated by the bias voltage generating circuit 13 are both equal to VDDM-Vth (i.e., V12=V13=VDDM-Vth).

In one embodiment, each of the diodes 40 and 41 can be implemented as a diode-connected N-type transistor. The circuit structure of the bias voltage generating circuits 12 and 13 in FIG. 4 is only an exemplary example, and the present invention is not limited thereto.

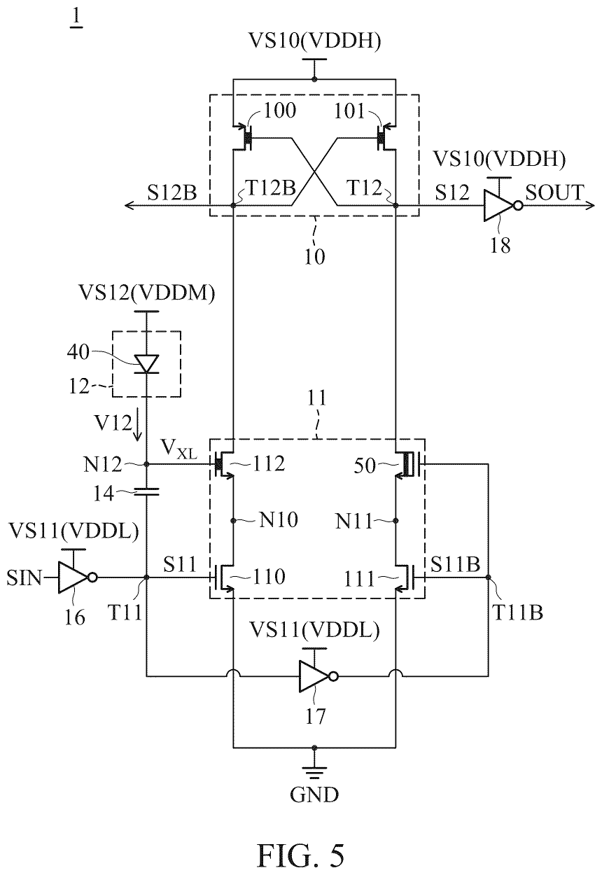

In other embodiments, the HV-NMOS transistor 113 is replaced by a native HV-NMOS transistor. As shown in FIG. 5, the level shifter 1 uses a natural HV-NMOS transistor 50 instead of the HV-NMOS transistor 113. In this embodiment, the level shifter 1 does not need to be equipped with the bias voltage generating circuit 13 and the capacitor 15. Referring to FIG. 5, the input terminal of the natural HV-NMOS transistor 50 is coupled to the output terminal T12, its output terminal is coupled to the node N11, and its control terminal is directly connected to the input terminal T11B. The natural HV-NMOS transistor 50 is always in the ON state. When the LV-NMOS transistor 111 is turned on, the output signal S12 switches down to a level of 0V. The operation of other components of the level shifter 1 in FIG. 5 can be found in the description of FIG. 2A to FIG. 3 and the description thereof will be omitted here.

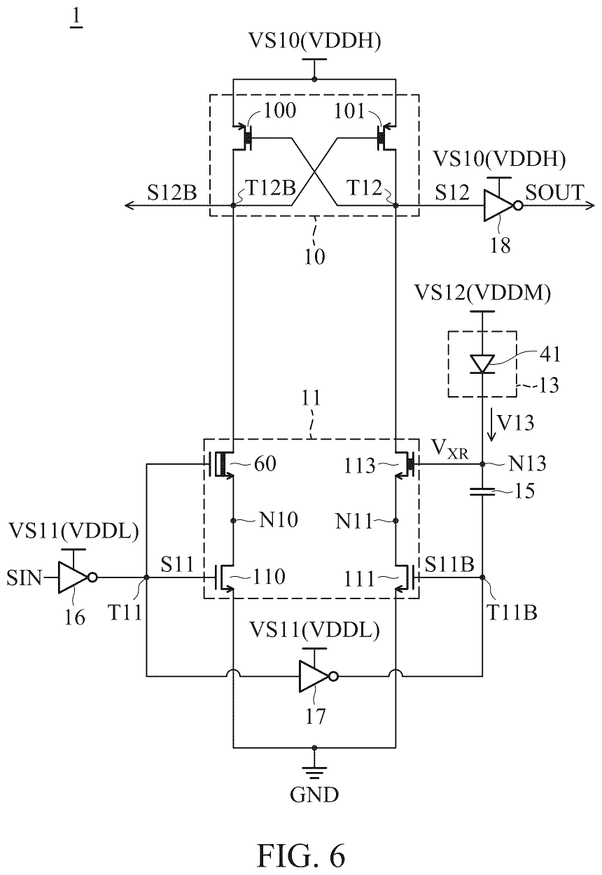

In other embodiments, the HV-NMOS transistor 112 is replaced by a natural HV-NMOS transistor. As shown in FIG. 6, the level shifter 1 uses a natural HV-NMOS transistor 60 instead of the HV-NMOS transistor 112. In this embodiment, the level shifter 1 does not need to be equipped with the bias voltage generating circuit 12 and the capacitor 14. Referring to FIG. 6, the input terminal of the natural HV-NMOS transistor 60 is coupled to the output terminal T12B, its output terminal is coupled to the node N10, and its control terminal is directly connected to the input terminal T11. The natural HV-NMOS transistor 60 is always in the ON state. When the LV-NMOS transistor 110 is turned on, the inverted output signal S12B switches down to a level of 0V. The operation of other components of the level shifter 1 in FIG. 6 can be found in the description of FIG. 2A to FIG. 3 and the description thereof will be omitted here.

In the above embodiments, the level shifter 1 includes inverters 16-18 as an example. In other embodiments, the inverters 16-18 are external components of the level shifter 1, i.e., the level shifter 1 does not include the inverters 16 to 18. The inverters 16 and 17 are used to provide the input signal S11 and the inverted input signal S11B to the level shifter 1. The inverter 18 receives the output signal S12 generated by the level shifter 1.

Although the present invention is disclosed above with preferred embodiments, it is not intended to limit the scope of the present invention. Any person having ordinary knowledge in the relevant technical field can make some modifications without departing from the spirit and scope of the present invention. Therefore, the scope of protection of the present invention shall be determined by the scope of the attached patent application.

What is claimed is:

1. A level shifter, comprising:
a high-voltage side circuit, coupled between a first voltage source, a first output terminal, and a second output terminal;
a first bias voltage generating circuit, configured to provide a first bias voltage to a first node;
a first capacitor, coupled between the first node and a first input terminal;
a first N-type transistor, having an input terminal coupled to the first output terminal, an output terminal coupled to a second node, and a control terminal coupled to the first node;
a second N-type transistor, having an input terminal coupled to the second node, an output terminal coupled to a ground, and a control terminal coupled to the first input terminal;
a third N-type transistor, having an input terminal coupled to the second output terminal, an output terminal coupled to a third node, and a control terminal coupled to a second input terminal; and
a fourth N-type transistor, having an input terminal coupled to the third node, an output terminal coupled to the ground, and a control terminal coupled to the second input terminal,
wherein the first input terminal receives a first input signal, the second input terminal receives a second input signal, and the first input signal and the second input signal are inversions of each other.

2. The level shifter as claimed in claim 1, wherein:
the first bias voltage generating circuit is coupled to a second voltage source to generate the first bias voltage,
the first voltage source receives a first supply voltage, and the second voltage source receives a second supply voltage,
each of the first input signal and the second input signal switches between a first voltage level and a second voltage level, wherein the second voltage level is lower than the first voltage level,
a level of the second supply voltage is higher than the first voltage level and is lower than or equal to a level of the first supply voltage.

3. The level shifter as claimed in claim 2, wherein the first bias voltage generating circuit comprises:
a diode, having an anode coupled to the second voltage source and a cathode coupled to the first node.

4. The level shifter as claimed in claim 1, wherein:
the first N-type transistor is a high-voltage transistor, and each of the second N-type transistor and the fourth N-type transistor is a low-voltage transistor, and
the control terminal of the third N-type transistor is directly connected to the second input terminal, and the third N-type transistor is a native transistor.

5. The level shifter as claimed in claim 1, further comprising:
a second bias voltage generating circuit, configured to provide a second bias voltage to a fourth node; and
a second capacitor, coupled between the fourth node and the second input terminal,
wherein the control terminal of the third N-type transistor is coupled to the fourth node.

6. The level shifter as claimed in claim 5, wherein:
each of the first N-type transistor and the third N-type transistor is a high-voltage transistor, and
each of the second N-type transistor and the fourth N-type transistor is a low-voltage transistor.

7. The level shifter as claimed in claim 5, further comprising:
a first inverter, powered by a second voltage source and coupled between the first input terminal and the second input terminal,
wherein the first inverter receives the first input signal and generates the second input signal at the second input terminal.

8. The level shifter as claimed in claim 7, wherein:
the first bias voltage generating circuit is coupled to a third voltage source to generate the first bias voltage,
the first voltage source receives a first supply voltage, the second voltage source receives a second supply voltage, and the third voltage source receives a third supply voltage, and
a level of the third supply voltage is higher than a level of the second supply voltage and is lower than or equal to a level of the first supply voltage.

9. The level shifter as claimed in claim 7, further comprising:
a second inverter, powered by the second voltage source,
wherein the second inverter has an input terminal configured to receive a third input signal and an output terminal coupled to the first input terminal.

10. The level shifter as claimed in claim 1, wherein the high-voltage side circuit comprises:
a first P-type transistor, having an input terminal coupled to the first voltage source, an output terminal coupled to the first output terminal, and a control terminal coupled to the second output terminal; and
a second P-type transistor, having an input terminal coupled to the first voltage source, an output terminal coupled to the second output terminal, and a control terminal coupled to the first output terminal.
